(19) United States
(12) Patent Application Publication
(10) Pub. No.: US 2007/0102814 A1
(43) Pub. Date: May 10, 2007

(54) Semiconductor device and method of manufacturing the same

(75) Inventor: Seung-Duk Baek, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/584,545

(22) Filed: Oct. 23, 2006

(30) Foreign Application Priority Data
Nov. 10, 2005 (KR) 10-2005-0107271

(51) Int. Cl. H01L 23/48

(52) U.S. Cl. 257/734

(57) ABSTRACT

In a method of manufacturing a semiconductor package, a semiconductor chip including a circuit unit that has a first circuit and a second circuit spaced apart from each other, a first conductive member for electrically connecting the first circuit to the second circuit and a cut-out portion for disconnecting the first and second circuits may be prepared. A test signal may be applied to the first circuit and the second circuit through the first conductive member to test the first and second circuits. The cut-out portion may be selectively removed in accordance with test results to divide the first conductive member into a first sub-conductive member electrically connected to the first circuit and a second sub-conductive member electrically connected to the second circuit. The first and second sub-conductive members may then be electrically connected to each other using a second conductive member.

### PRIORITY STATEMENT

This application claims priority under 35 USC § 119 to Korean Patent Application No. 2005-107271, filed on Nov. 10, 2005, in the Korean Intellectual Property Office (KIPO), the entire contents of which are herein incorporated by reference.

### BACKGROUND

1. Field

Example embodiments relate to a semiconductor device and a method of manufacturing the semiconductor device. Other example embodiments relate to a semiconductor device that may be capable of reducing noise and a method of manufacturing the semiconductor device.

2. Description of the Related Art

As the technology of manufacturing semiconductor chips has been developed, integration degrees of the semiconductor chips also have been improved. Generally, the semiconductor chip formed on a silicon substrate may be damaged by impacts from the outside (e.g., moisture and/or oxygen). Most semiconductor chips may be bundled by a package process to protect the semiconductor chips from outside physical impacts (e.g., moisture and/or oxygen). Recently, chip scale packages (e.g., a ball grid array (BGA) package and/or a wafer level package) have been developed. The chip scale package may have a volume substantially similar to that of the semiconductor device.

A volume and an area of the semiconductor chip may be gradually increased in proportion to an increasing number of circuit units integrated in the semiconductor chip. In general, circuit units formed in the semiconductor chip may be electrically connected to each other using a conductive wire having a several micrometers width. When the circuit units in the semiconductor chip are spaced apart from each other, a driving signal applied to the conductive wire may be deteriorated due to electrical resistance of the conductive wire.

To retard and/or prevent the driving signal applied to the circuit units from being deteriorated, a signal repeater for relaying the driving signal may be installed in the conductive wire. Although the signal repeater is installed in the wire, the signal deterioration may still be generated in the conductive wire and an operating speed of the semiconductor chip may be decreased due to the signal repeater installed in the wire.

### SUMMARY

Example embodiments provide a semiconductor device that may be capable of reducing deterioration of a driving signal applied to circuit units in a semiconductor chip electrically coupled to each other. Example embodiments provide a method of manufacturing the above-mentioned semiconductor device.

In accordance with example embodiments, the semiconductor device may include a semiconductor chip having a circuit unit and a first conductive member and a second conductive member. The circuit unit may include a first circuit and a second circuit spaced apart from each other. The first conductive member may electrically, yet selectively, connect the first and second circuits. The second conductive member may be electrically connected the semiconductor to the circuit unit.

In a method of manufacturing the semiconductor package in accordance with example embodiments, a semiconductor chip including a circuit unit that has a first circuit and a second circuit spaced apart from each other and a first conductive member for electrically connecting the first circuit to the second circuit may be formed. A second conductive member may be formed electrically coupled between the first and second circuits.

The method may further include forming a cut-out portion for disconnecting the first and second circuits and applying a test signal to the first circuit and the second circuit through the first conductive member to test the first and second circuits. The cut-out portion may be selectively removed in accordance with test results to divide the first conductive member into a first sub-conductive member electrically connected to the first circuit and a second sub-conductive member electrically connected to the second circuit. The first and second sub-conductive members may then be electrically connected to each other using a second conductive member.

### BRIEF DESCRIPTION OF THE DRAWINGS

Example embodiments will be more clearly understood from the following detailed description taken in conjunction with the accompanying drawings. FIGS. 1-19 represent non-limiting, example embodiments as described herein.

FIGS. 1-10 are diagrams illustrating semiconductor devices in accordance with example embodiments;

FIGS. 11-15 are diagrams illustrating a method of manufacturing a semiconductor chip in accordance with example embodiments;

FIG. 16 is a diagram illustrating a second metal layer and a photoresist pattern on the semiconductor chip in accordance with example embodiments;

FIG. 17 is a diagram illustrating a second conductive pattern formed by patterning the second metal layer in FIG. 16;

FIG. 18 is a diagram illustrating a semiconductor chip in accordance with example embodiments; and

FIG. 19 is a diagram illustrating a semiconductor chip in FIG. 18 mounted on the substrate.

### DESCRIPTION OF EXAMPLE EMBODIMENTS

Example embodiments are described more fully hereinafter with reference to the accompanying drawings, in which example embodiments are shown. Example embodiments may, however, be embodied in many different forms and should not be construed as limited to the embodiments set forth herein. Rather, these embodiments are provided so that this disclosure will be thorough and complete and will fully convey the scope of example embodiments to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below.” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements and/or components, but do not preclude the presence or addition of one or more other features, integers, steps, operations, elements, components and/or groups thereof.

Example embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Semiconductor Device

FIG. 1 is a diagram illustrating a semiconductor device in accordance with example embodiments. Referring to FIG. 1, a semiconductor device 300 may include a semiconductor chip 100 having a circuit unit 130 and a first conductive member 140 and a second conductive member 200. The circuit unit 130 of the semiconductor chip 100 may include a plurality of circuits. A pair of circuits, spaced apart from each other by a given interval, may be defined as a first circuit 110 and a second circuit 120.

A driving signal may be transferred from the first circuit 110 to the second circuit 120. On the contrary, the driving signal may be transferred from the second circuit 120 to the first circuit 110. In example embodiments, the driving signal, for example, may have a clock signal having a digital signal format. The first conductive member 140 may be selectively electrically coupled between the first circuit 110 and the second circuit 120. The driving signal may be applied to the first circuit 110 and/or the second circuit 120 through the first conductive member 140. In example embodiments, the first conductive member 140 may have a first width, a first electrical resistance and a first thickness.

For example, the first conductive member 140 may be formed by patterning a conductive layer having the first thickness, so that the first conductive member 140 having the first width has the first electrical resistance. Because the first conductive member 140 is formed by etching the conductive layer having a first thickness, the first conductive member 140 may have the relatively high first electrical resistance. When the driving signal is applied to the first conductive member 140, the driving signal may be deteriorated by the first electrical resistance.

To retard and/or prevent the driving signal from being deteriorated by the first electrical resistance of the first conductive member 140, the first conductive member 140 may have a cut-out portion 145. When the first circuit 110 and the second circuit 120 are normally operated, the cut-out portion 145 of the first conductive member 140, electrically coupled between the first and second circuits 110 and 120, may be removed using a laser beam, so that the first circuit 110 may be disconnected from the second circuit 120. In example embodiments, examples of a material that may be used for the first conductive member 140 may include aluminum, chromium, tungsten, titanium and/or copper. These may be used alone and/or in a combination thereof.

When the first conductive member 140 has two cut-out portions 145, the first conductive member 140 may be divided into a first sub-conductive member 141, a second sub-conductive member 142 and a third sub-conductive member 143 arranged between the first and second sub-conductive members 141 and 142. Alternatively, when the first conductive member 140 has only one cut-out portion 145, the first conductive member 140 may be divided into the first sub-conductive member 141 and the second sub-conductive member 142. In example embodiments, the first conductive member 140 may have two cut-out portions 145.

The second conductive member 200 may be electrically coupled between the first circuit 110 and the second circuit 120. The second conductive member 200 may have a first end and a second end opposite to the first end. The first end may be electrically connected to the first sub-conductive member 141. The second end may be electrically connected to the second sub-conductive member 142. In example embodiments, examples of a material that may be used for the second conductive member 200 may include copper, gold, sliver, solder and/or aluminum. These may be used alone and/or in a combination thereof.

In example embodiments, the second conductive member 200 may have a second width wider than the first width of the first conductive member 140, a second electrical resistance lower than the first electrical resistance of the first conductive member 140 and a second thickness greater than the first thickness of the first conductive member 140. For example, the second conductive member 140 may be formed by patterning a conductive layer having the second thickness, so that the second conductive member having the second width has the second electrical resistance. The driving signal may be transferred from the first circuit 110 to the second circuit 120 through the second conductive member 200, having improved electrical characteristics, instead of the first conductive member 140, thereby reducing noise caused by deteriorating the driving signal.

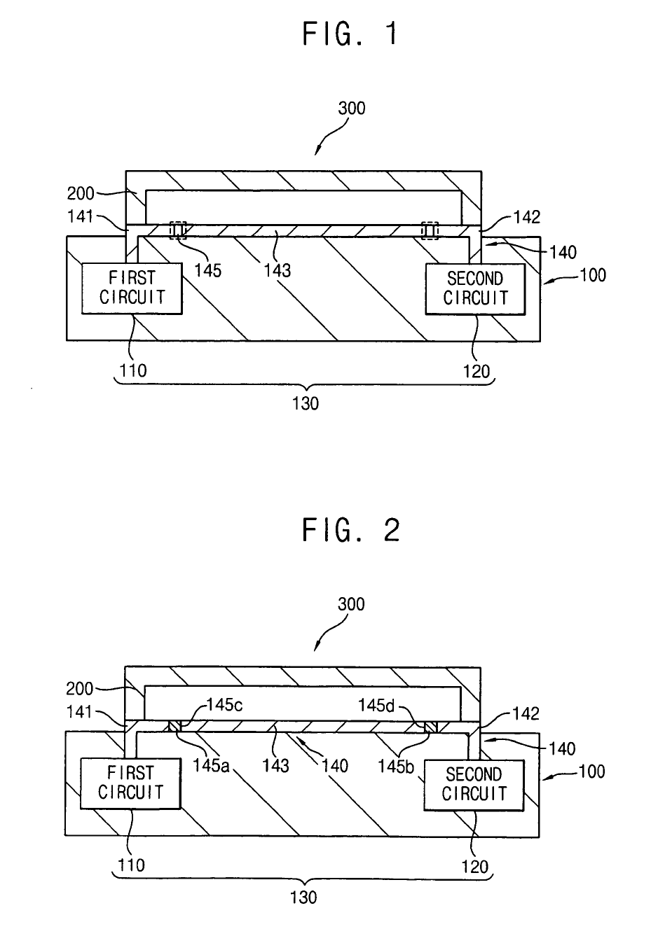

FIG. 2 is a diagram illustrating a semiconductor device in accordance with example embodiments. Referring to FIG. 2, a semiconductor device 300 may include a semiconductor chip 100 having a circuit unit 130 and a first conductive member 140 and a second conductive member 200. The circuit unit 130 may include a first circuit 110 and a second circuit 120.

The first conductive member 140 may include a first fuse 145a and a second fuse 145b. The first conductive member 140 may have at least one cut-out portion. The cut-out portion may be formed by removing the first conductive member 140 using a laser beam. In example embodiments, the first conductive member 140 may have two cut-out portions 145c and 145d. The first conductive member 140 may be divided into the first sub-conductive member 141, the second sub-conductive member 142 and the third sub-conductive member 143.

The first fuse 145a may be placed in a first cut-out portion 145c formed between the first sub-conductive member 141 and the third sub-conductive member 143. The first fuse 145a may be electrically coupled between the first sub-conductive member 141 and the third sub-conductive member 143. The second fuse 145b may be placed in a second cut-out portion 145d formed between the second sub-conductive member 142 and the third sub-conductive member 143. The second fuse 145b may electrically connect the second sub-conductive member 142 and the third sub-conductive member 143.

When the first circuit 110 and the second circuit 120 are normally operated, the first and second fuses 145a and 145b may be melted by heat and/or light (e.g., a laser beam), so that the first conductive member 140 may be divided into the first, second and third sub-conductive members 141, 142 and 143. When the first conductive member 140 is divided into the first, second and third sub-conductive members 141, 142 and 143, the driving signal may be transferred from the first circuit 110 to the second circuit 120 through the second conductive member 200, having improved electrical characteristics, instead of the first conductive member 140, thereby reducing noise caused by deteriorating the driving signal.

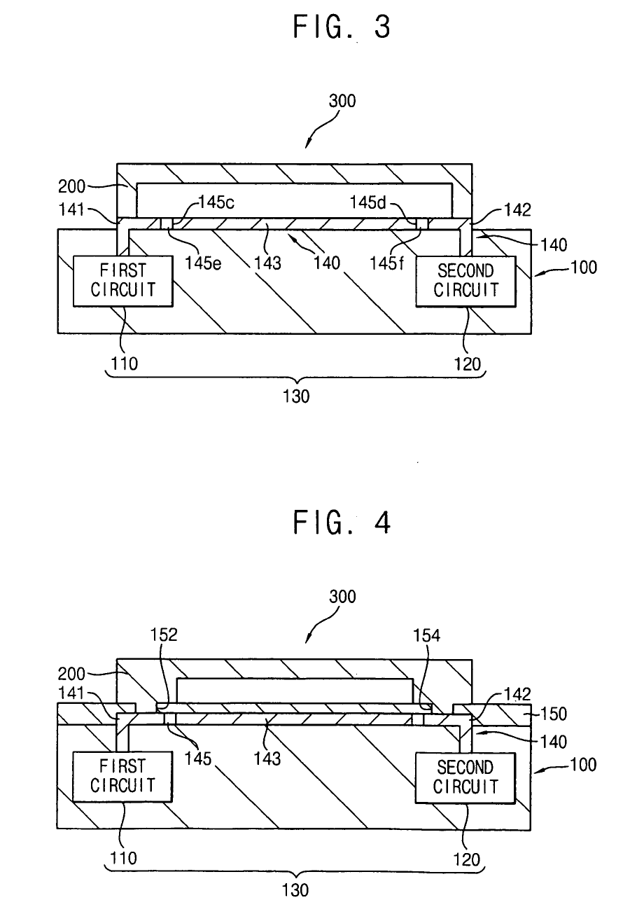

FIG. 3 is a diagram illustrating a semiconductor device in accordance with example embodiments. Referring to FIG. 3, a semiconductor device 300 may include a semiconductor chip 100 having a circuit unit 130 and a first conductive member 140 and a second conductive member 200. The circuit unit 130 may include a first circuit 110 and a second circuit 120.

The first conductive member 140 may include a first switching element 145e and a second switching element 145f. The first conductive member 140 may have at least one cut-out portion. The cut-out portion may be formed by removing the first conductive member 140 using a laser beam. In example embodiments, the first conductive member 140 may have first and second cut-out portions 145c and 145d. The first conductive member 140 may be divided into the first sub-conductive member 141, the second sub-conductive unit 142 and the third sub-conductive member 143.

The first switching element 145e may be placed in the first cut-out portion 145c formed between the first sub-conductive member 141 and the third sub-conductive member 143. The first switching element 145e may be electrically coupled between the first sub-conductive member 141 and the third sub-conductive member 143. The second switching element 145f may be placed in the second cut-out portion 145d formed between the second sub-conductive member 142 and the third sub-conductive member 143. The second switching element 145f may electrically connect the second sub-conductive member 142 and the third sub-conductive member 143. In example embodiments, the first switching element 145e and the second switching element 145f may include a thin film transistor that is manufactured by various semiconductor manufacturing processes and/or a small size transistor.

While a transistor driving signal for driving the first and second switching elements 145e and 145f is applied to the first and second switching elements 145e and 145f, the first sub-conductive member 141, the second sub-conductive member 142 and the third sub-conductive member 143 may be electrically connected to one another through the first and second switching elements 145e and 145f. When the transistor driving signal for driving the first and second switching elements 145e and 145f is not applied to the first and the second switching elements 145e and 145f, the first sub-conductive member 141, the second sub-conductive member 142 and the third sub-conductive member 143 may be electrically disconnected from one another.

When the first circuit 110 is disconnected from the second circuit 120 using the first switching element 145e and the second switching element 145f, the driving signal may be transferred from the first circuit 110 to the second circuit 120 through the second conductive member 200, having improved electrical characteristics, instead of the first conductive member 140. Noise caused by deteriorating the driving signal may be reduced.

FIG. 4 is a diagram illustrating a semiconductor device in accordance with example embodiments. Referring to FIG. 4, a semiconductor device 300 may include a semiconductor chip 100 having a circuit unit 130, a first conductive member 140 and a passivation layer 150 and a second conductive member 200. The circuit unit 130 may include a first circuit 110 and a second circuit 120.

The passivation layer 150 may be placed on an upper face of the semiconductor chip 100 having the first conductive member 140. The passivation layer 150 may cover the first conductive member 140 to insulate the first conductive member 140 from an exterior conductive body. The passivation layer 150 may absorb an impact applied from the exterior to retard and/or prevent elements of the semiconductor chip 110 from being damaged. In example embodiments, the passivation layer 150 may be formed on the upper face of the semiconductor chip 100 by a spin coating process, a chemical vapor deposition (CVD) process and/or any other suitable process.

The passivation layer 150 may include a first aperture 152 and a second aperture 154. The first and second apertures 152 and 154 may be formed through the passivation layer 150. The first aperture 152 may expose the first sub-conductive member 141 of the first conductive member 140. The second aperture 154 may expose the second sub-conductive member 142 of the first conductive member 140. A first end of the second conductive member 200 may be electrically coupled to a first exposed portion of the first sub-conductive member 141 exposed through the first aperture 152 of the passivation layer 150.

A second end of the second conductive member 200 opposite to the first end may be electrically connected to a second exposed portion of the second sub-conductive member 142 exposed through the second aperture 154 of the passivation layer 150. When the first circuit 110 is disconnected from the second circuit 120 using the cut-out portion 145, for example, the fuse and/or the switching element, the driving signal may be transferred from the first circuit 110 to the second circuit 120 through the second conductive member 200 having improved electrical characteristics, instead of the first conductive member 140, thereby reducing noise caused by deteriorating the driving signal.

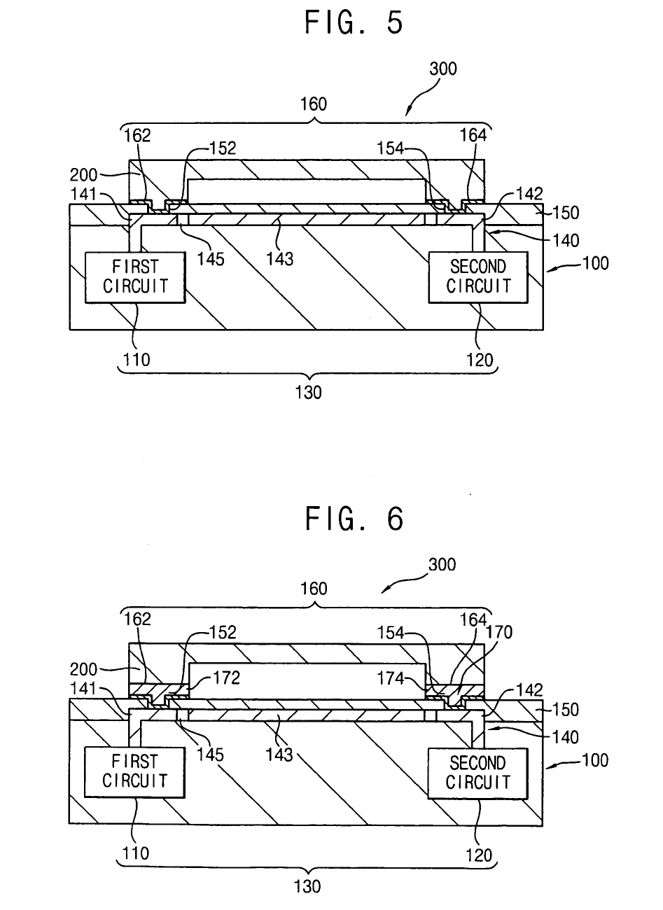

FIG. 5 is a diagram illustrating a semiconductor device in accordance with example embodiments. Referring to FIG. 5, a semiconductor device 300 may include a semiconductor chip 100 having a circuit unit 130, a first conductive member 140, a passivation layer 150 and a conductive pad 160 and a second conductive member 200. The circuit unit 130 may include a first circuit 110 and a second circuit 120. The conductive pad 160 may include a first pad 162 and a second pad 164.

The passivation layer 150 may include the first aperture 152 and the second aperture 154. The first and second apertures 152 and 154 may be formed through the passivation layer 150. The first aperture 152 may expose the first sub-conductive member 141 of the first conductive member 140. The second aperture 154 may expose the second sub-conductive member 142 of the first conductive member 140.

The first sub-conductive member 141 of the first conductive member 140 partially exposed through the first aperture 152 of the passivation layer 150 may be electrically coupled to the first pad 162. The second sub-conductive member 142 of the first conductive member 140 partially exposed through the second aperture 154 of the passivation layer 150 may be electrically connected to the second pad 164.

A first end of the second conductive member 200 may be stably electrically connected to the first pad 162 formed on the first conductive unit 141. A second end of the second conductive member 200 may be stably electrically coupled to the second pad 164 formed on the second conductive unit 142. In example embodiments, examples of a material that may be used for the first and second conductive pads 162 and 164 may include gold, silver, copper, aluminum, aluminum alloy and/or nickel. These may be used alone and/or in a combination thereof.

When the first circuit 110 is disconnected from the second circuit 120 using the cut-out portion, for example, the fuses and/or the switching elements, the driving signal may be transferred from the first circuit 110 to the second circuit 120 through the second conductive member 200, having improved electrical characteristics, instead of the first conductive member 140 to reduce noise caused by deteriorating the driving signal.

FIG. 6 is a diagram illustrating a semiconductor device in accordance with example embodiments. Referring to FIG. 6, a semiconductor device 300 may include a semiconductor chip 100 having a circuit unit 130, a first conductive member 140, a passivation layer 150, a conductive pad 160 and a conductive bump 170 and a second conductive member 200. The circuit unit 130 may include a first circuit 110 and a second circuit 120. The conductive pad 160 may include a first pad 162 and a second pad 164.

The passivation layer 150 may include a first aperture 152 and a second aperture 154. The first and second apertures 152 and 154 may be formed through the passivation layer 150. The first aperture 152 may expose the first sub-conductive member 141 of the first conductive member 140. The second aperture 154 may expose the second sub-conductive member 142 of the first conductive member 140.

The first sub-conductive member 141 of the first conductive member 140 partially exposed through the first aperture 152 of the passivation layer 150 may be electrically coupled to the first pad 162. The second sub-conductive member 142 of the first conductive member 140 partially exposed through the second aperture 154 of the passivation layer 150 may be electrically connected to the second pad 164.

A first end of the second conductive member 200 may be stably electrically connected to the first pad 162 formed on the first sub-conductive member 141. A second end of the second conductive member 200 may be stably electrically connected to the second pad 164 formed on the second sub-conductive member 142. In example embodiments, examples of a material that may be used for the first and second pads 162 and 164 may include gold, silver, copper, aluminum, aluminum alloy and/or nickel. These may be used alone and/or in a combination thereof.

The conductive bump 170 may include a first bump 172 and a second bump 174. The first bump 172 may be electrically coupled to the first pad 162 of the conductive pad 160. The second bump 174 may be electrically connected to the second pad 164 of the conductive pad 160. The first and second bumps 172 and 174 may improve electrical contact characteristics between the first sub-conductive member 141 and the second conductive member 200 and between the second sub-conductive member 142 and the second conductive member 200. Examples of a material that may be used for the first and second conductive bumps 172 and 174 may include solder, gold, silver and/or copper. These may be used alone and/or in a combination thereof.

When the first circuit 110 is disconnected from the second circuit 120 using the cut-out portion, for example, the fuses and/or the switching element, the driving signal may be transferred from the first circuit 110 to the second circuit 120 through the second conductive member 200, having improved electrical characteristics, instead of the first conductive member 140. Noise caused by deteriorating the driving signal may be reduced.

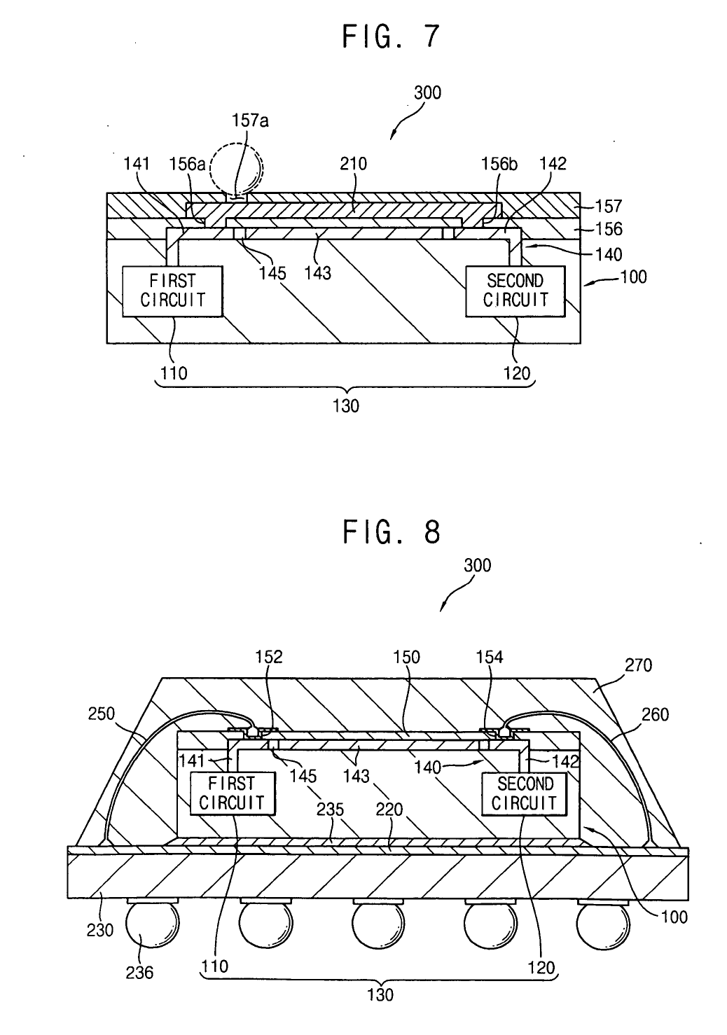

FIG. 7 is a diagram illustrating a semiconductor device in accordance with example embodiments. Referring to FIG. 7, a semiconductor device 300 may include a semiconductor chip 100 having a circuit unit 130, a first conductive member 140, a first passivation layer 156 and a second passivation layer 157 and a second conductive member 210. The circuit unit 130 may include a first circuit 110 and a second circuit 120.

The first passivation layer 156 may be placed on an upper face of the first conductive member 140 having the cut-out portion 145 for dividing the first conductive member 140 into the first and second sub-conductive members 141 and 142. The first passivation layer 156 formed on the upper face of the semiconductor chip 100 may cover the first conductive member 140 to insulate the first conductive member 140 from an external conductive body. The first passivation layer 156 may absorb an impact from the outside to retard and/or prevent elements of the semiconductor chip 100 from being damaged. In example embodiments, the first passivation layer 156 may be formed on the upper face of the semiconductor chip 100 by a spin coating process and/or a CVD process.

The first passivation layer 156 may include a first aperture 156a and a second aperture 156b. The first aperture 156a may be formed through the first passivation layer 156, so that the first sub-conductive member 141 may be partially exposed through the first aperture 156a. The second aperture 156b may be formed through the first passivation layer 156, so that the second sub-conductive member 142 may be partially exposed through the second aperture 156b.

The second conductive member 210 may be placed on an upper face of the first passivation layer 156 having the first and second apertures 156a and 156b. The second conductive member 210 may be formed by patterning a conductive layer formed on the first passivation layer 156. Various dimensions (e.g., a width, an area and/or a thickness) of the second conductive member 210 may be larger than those of the first conductive member 140. Electrical characteristics of the second conductive member 210 may be improved compared to those of the first conductive member 140. In example embodiments, examples of a material that may be used for the second conductive member 210 may include gold, silver, copper, aluminum and/or aluminum alloy. These may be used alone and/or in a combination thereof.

The second passivation layer 157 may be placed on the first passivation layer 156. The second passivation layer 157 may insulate the second conductive member 210 formed on the first passivation layer 156 from an external conductive body. In example embodiments, the second passivation layer 157 may further include a third aperture 157a that partially exposes the second conductive member 210. A conductive ball (e.g., a solder ball) may be mounted on the exposed second conductive member 210 through the third aperture 157a.

In example embodiments, when the first conductive member 140, the first passivation layer 156, the second conductive member 210 and the second passivation layer 157 may be arranged in an order described above, from the upper face of the semiconductor chip 100, an area of the semiconductor device may be substantially the same as the semiconductor chip 100, thereby reducing a dimension of the semiconductor device.

When the first circuit 110 is disconnected from the second circuit 120 using the cut-out portion, for example, the fuses and/or the switching elements, the driving signal may be transferred from the first circuit 110 to the second circuit 120 through the second conductive member 210, having improved electrical characteristics, instead of the first conductive member 140. Noise caused by deteriorating the driving signal may be reduced.

FIG. 8 is a diagram illustrating a semiconductor device in accordance with example embodiments. Referring to FIG. 8, a semiconductor device 300 may include the semiconductor chip 100, a second conductive member 220 and a substrate 230. The semiconductor chip 300 may include the first circuit 110, the second circuit 120, the conductive member 140 and the passivation layer 150. The first conductive member 140 may have a first sub-conductive member 141, a second sub-conductive member 142 and a third sub-conductive member 143. The passivation layer 150 may have the first aperture 152 that exposes the first sub-conductive member 141 and the second aperture 154 that exposes the second sub-conductive member 142.

The second conductive member 220 may be formed on the substrate 230. In example embodiments, the second conductive member 220 may have improved electrical characteristics compared to that of the first conductive member 140. In example embodiments, the substrate 230 may include a synthetic resin substrate having a polyimide resin and/or a printed circuit board (PCB). The substrate 230 further may include a plurality of signal wires as well as the second conductive member 220.

In example embodiments, the substrate 230 may be positioned beneath the lower face of the semiconductor chip 100 opposite to the upper face. For example, the semiconductor chip 100 may be attached to the lower face of the substrate 230 using the adhesive member 235 (e.g., a both-side adhesive tape and/or an adhesive material). The first sub-conductive member 141 of the semiconductor chip 100 may be electrically coupled to a second conductive member 220 through a first conductive wire 250. The second sub-conductive member 142 of the semiconductor chip 100 may be electrically connected to the second conductive member 220 through a second conductive wire 260. A mold member 270, having an epoxy resin, may encapsulate the semiconductor chip 100, the first conductive wire 250 and the second conductive wire 260 on the substrate 230.

A plurality of conductive balls 236 (e.g., solder balls) for applying a driving signal to the semiconductor chip 100 may be formed beneath a lower face of the substrate 230. When the first conductive member 140 is electrically disconnected by the cut-out portion 145, for example, the fuses and/or the switching element, the first driving signal may be transferred to second circuit 120 through the first conductive wire 250, the second conductive member 220 and the second conductive wire 260 instead of the first conductive member 140. Noise caused by deteriorating the driving signal may be reduced.

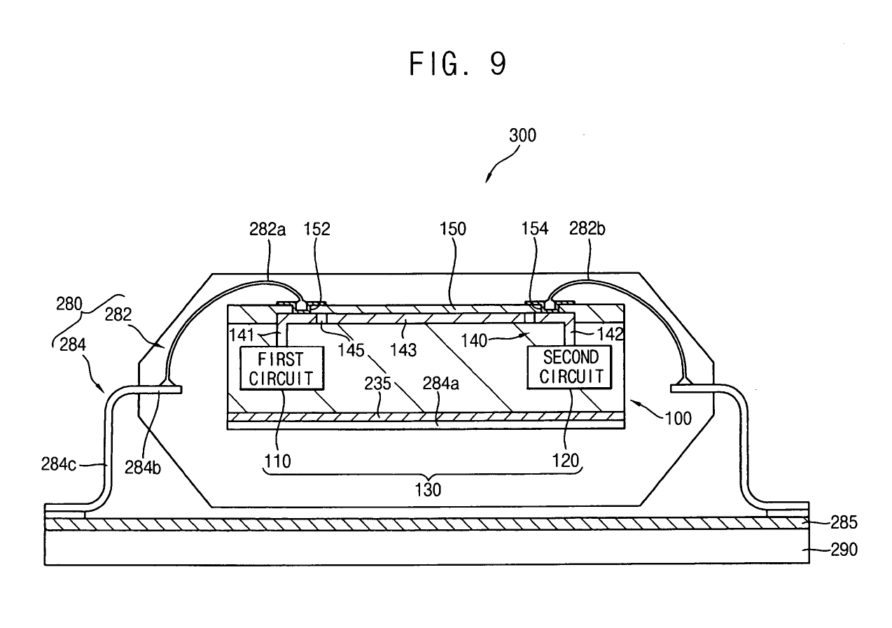

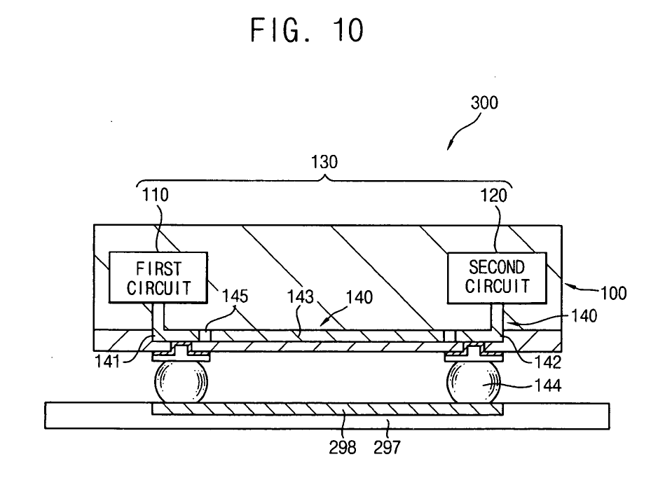

FIG. 9 is a diagram illustrating a semiconductor device in accordance with example embodiments. Referring to FIG. 9, a semiconductor device 300 may include the semiconductor chip 100 having the first conductive member 140, the second conductive member 285, a conductive connecting member 280 and a substrate 290.

The semiconductor device 300 may include the first circuit 110, the second circuit 120, the first conductive member 140 and the passivation layer 150. The first conductive member 140 may have the first sub-conductive member 141, the second sub-conductive member 142 and a third sub-conductive member 143. The passivation layer 150 may have the first aperture 152 that exposes the first sub-conductive member 141 and the second aperture 154 that exposes the second sub-conductive member 142.

The second conductive member 285 may be formed on the substrate 290. In example embodiments, the second conductive member 285 may have improved electrical characteristics compared to that of the first conductive member 140. In example embodiments, the substrate 230 (shown in FIG. 8) may include a synthetic resin substrate having a polyimide resin and/or a PCB. The substrate 230 (shown in FIG. 8) may include a plurality of signal wires and the second conductive member 285. The first sub-conductive member 141 may be electrically connected to the second sub-conductive member 142 through the conductive connecting member 280. In example embodiments, the conductive connecting member 280 may include a lead frame 284 and conductive wires 282.

The lead frame 284 may include a die pad 284a for supporting the semiconductor chip 100, an inner lead 284b and an outer lead 284c that extends from the inner lead 284a. The conductive wire 282 may include a first conductive wire 282a and a second conductive wire 282b. The first conductive wire 282a may electrically connect the first circuit 110 and the inner lead 284b. The second conductive wire 282b may be electrically coupled between the second circuit 120 and another inner lead 284b. The first circuit 110 may be electrically connected to the second conductive member 285 through the first sub-conductive member 141, the first conductive wire 282a and the inner lead 284b. The second circuit 120 may be electrically coupled to the second conductive member 285 through the second sub-conductive member 142, the second conductive wire 282b and another inner lead 284b.

In example embodiments, the semiconductor chip 100, the first conductive wire 250 and the second conductive wire 260, which is formed on the substrate 230 (see FIG. 8), may be encapsulated with a mold member 270 (see FIG. 8) including an epoxy resin. When the first conductive member 140 may be electrically disconnected by the cut-out portion 145, for example, the fuses and/or the switching element, the first driving signal may be transferred to second circuit 120 through the conductive wire 282 having an excellent electrical characteristic, instead of the first conductive member 140, the lead frame 284 and the second conductive member 285. Noise caused by deteriorating the driving signal may be reduced.

FIG. 10 is a diagram illustrating a semiconductor device in accordance with example embodiments. Referring to FIG. 10, a semiconductor device 300 may include the semiconductor chip 100 having the first conductive member 140, a second conductive member 298 and a substrate 297.

The semiconductor chip 100 may include the first circuit 110, the second circuit 120 and the first conductive member 140. The first conductive member 140 may have the first sub-conductive member 141, the second sub-conductive member 142 and the third sub-conductive member 143. In example embodiments, conductive balls 144 (e.g., solder balls) may be mounted on the first sub-conductive member 141 and the second sub-conductive member 142, respectively.

In example embodiments, the second conductive member 298 may be placed on the substrate 297. The second conductive member 298 may have improved electrical characteristics compared to that of the first conductive member 140. In example embodiments, the substrate 297 may include a polyimide substrate having polyimide resin (e.g., a PCB).

The semiconductor chip 100 having the conductive balls 144 that are mounted on the first sub-conductive member 141 and the second sub-conductive member 142 may be placed on the substrate 297 in a flip-chip manner. The conductive balls 144 mounted on the first and second sub-conductive members 141 and 142 may face the second conductive member 298 formed on the substrate 297. The conductive balls 144 may be electrically soldered to the second conductive member 298 formed on the substrate 297.

When the first conductive member 140 may be electrically disconnected by the cut-out portion 145, for example, the fuses and/or the switching element, the first driving signal may be transferred to second circuit 120 through the conductive ball 144 formed on the substrate and the second conductive member 298 instead of the first conductive member 140. Noise caused by deteriorating the driving signal may be reduced.

Method of Manufacturing a Semiconductor Device

FIG. 11 is a diagram illustrating a semiconductor chip in accordance with example embodiments. Referring to FIG. 11, processes for forming a semiconductor chip may be carried out on the wafer (e.g., a silicon substrate) to form a first circuit 110 and a second circuit 120 in the wafer. A first metal layer (not shown) may be formed on the wafer to cover the first circuit 110 and the second circuit 120. The first metal layer may be formed by a sputtering process, a chemical vapor deposition (CVD) process and/or any other suitable process. In example embodiments, examples of a material that may be used for the first metal layer may include aluminum, aluminum alloy, silver, gold and/or copper. These may be used alone and/or in a combination thereof.

A photoresist film (not shown) may be formed on the first metal layer. The photoresist film may be formed by a spin coating process. The photoresist film may be patterned by a photolithography process including an exposing process and a developing process, thereby forming a photoresist pattern (not shown) on the first metal layer. The first metal layer may be etched using the photoresist pattern as an etching mask to form a first conductive member 140 on the wafer. In example embodiments, the first circuit 110 may be electrically coupled to the second circuit 120 through the first conductive member 140.

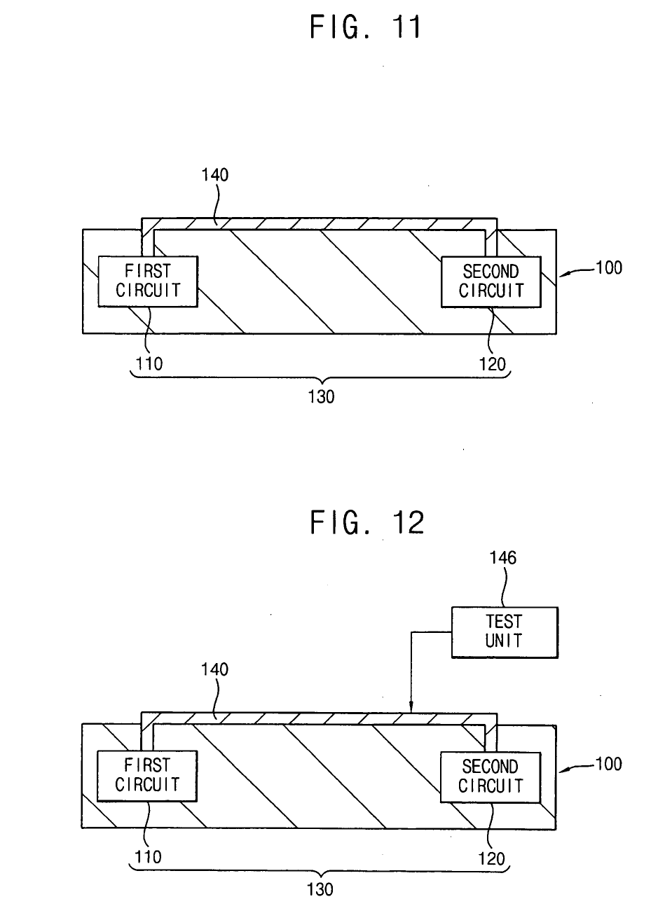

FIG. 12 is a diagram illustrating a step for testing the first and second circuits in FIG. 11. Referring to FIG. 12, after forming the first circuit 110, a second circuit 120 and the first conductive member 140 on the wafer, the first circuit 110 and the second circuit 120 may be tested using a test unit 146. The test unit 146 may apply a test signal to the first conductive member 140.

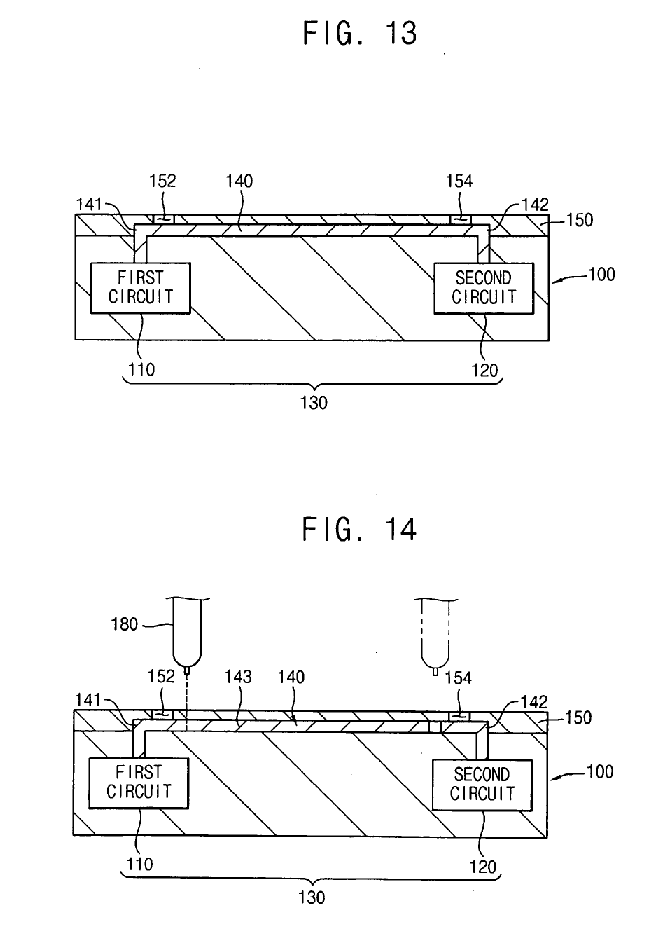

FIG. 13 is a diagram illustrating a passivation layer on the wafer in FIG. 12. A passivation layer 150 including an oxide layer and/or a nitride layer may be formed on the first conductive member 140 and the wafer 100. The passivation layer 150 may be formed by a CVD process. After forming the passivation layer 150 on the wafer, a photoresist film (not shown) may be formed on the passivation layer 150. The photoresist film may be formed by a spin coating process. The photoresist film may be patterned by a photolithography process including an exposing process and a developing process, thereby forming a photoresist pattern on the passivation layer 150.

In example embodiments, at least two portions of the passivation layer 150 corresponding to the first conductive member 140 may be exposed through the photoresist pattern. The passivation layer 150 may be dry etched using the photoresist pattern as an etching mask to form a first aperture 152 and a second aperture 154 that partially expose the first conductive member 140 through the passivation layer 150.

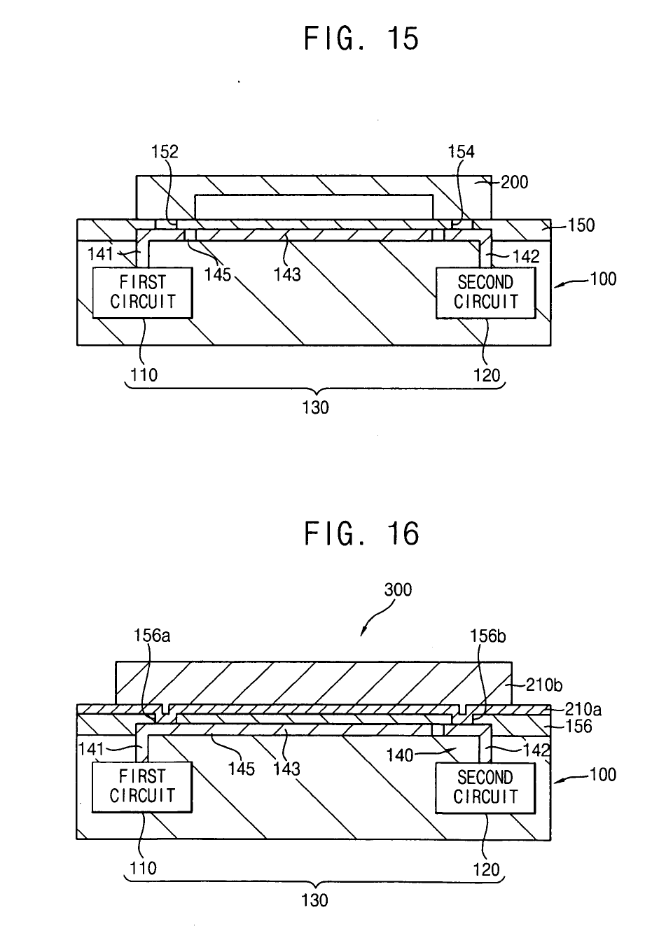

FIG. 14 is a diagram illustrating a step for electrically separating the first conductive member disposed beneath the passivation layer in FIG. 13 using a laser beam. Referring to FIG. 14, after forming the passivation layer 150 having the first aperture 152 and the second aperture 154 on the wafer, at least one portion of the first conductive member 140 may be removed using a laser beam generated from a laser beam generating unit 180. In example embodiments, two portions of the first conductive member 140 spaced apart from each other may be removed by the laser beam.

The first conductive member 140 may be divided into a first sub-conductive member 141, a second sub-conductive member 142 and a third sub-conductive member 143. The first sub-conductive member 141 may be partially exposed through the first aperture 152 of the passivation layer 150. The second sub-conductive member 142 may be partially exposed through the second aperture 154. After manufacturing the semiconductor chip 100, conductive pads (not shown) may be further formed on the first sub-conductive member 141 and the second sub-conductive member 142, respectively. Additionally, conductive bumps may be further formed on the conductive pads.

FIG. 15 is a diagram illustrating a second conductive member formed on the semiconductor chip in FIG. 14. Referring to FIG. 15, the first conductive unit 110 may be electrically coupled to the second conductive unit 120 through a second conductive member 200. In example embodiments, electrical characteristics of the second conductive member 200 may be improved compared to that of the first conductive member 140. In example embodiments, examples of a material that may be used for the second conductive member 200 may include copper, solder, aluminum, aluminum alloy, gold and/or silver. These may be used alone and/or in a combination thereof.

Referring to FIG. 8, a substrate 230 having the second conductive member 220 may be adhered to a lower face of the semiconductor chip 100 using an adhesive member 235. The first conductive unit 141 of the semiconductor chip 100 may be electrically coupled to the second conductive member 220 through a first conductive wire 250. The second conductive unit 142 of the semiconductor chip 100 may be electrically connected to the second conductive member 220 through a second conductive wire 260. The semiconductor chip 100, the first conductive wire 250 and the second conductive wire 260 may be molded using a synthetic resin (e.g., an epoxy resin). A plurality of conductive balls (e.g., solder balls) for applying a driving signal to the semiconductor chip may be placed on the substrate 230.

FIG. 16 is a diagram illustrating a second metal layer and a photoresist pattern, which may be formed on the semiconductor chip in accordance with example embodiments. Referring to FIG. 16, after the cut-out portion 145 is removed to electrically divide the first conductive member 140 into the first sub-conductive member 141 and the second sub-conductive member 142, a first passivation layer 156 may be formed on the first conductive member 140. The first passivation layer 156 may cover the first conductive member 140 to insulate the first conductive member 140 from an external conductive body. The first passivation layer 156 may be formed by a spin coating process, a CVD process and/or any other suitable process. A first aperture 156a for partially exposing the first sub-conductive member 141 of the first conductive member 140 and a second aperture 156b for partially exposing the second sub-conductive member 142 of the first conductive member 140 may be formed through the first passivation layer 156.

A second metal layer 210a may be formed on an entire upper face of the passivation layer 156 having the first aperture 156a and the second aperture 156b. The second metal layer may be formed by a sputtering process, a CVD process and/or any other suitable process. After forming the second metal layer on the passivation layer 156, a photoresist film (not shown) may be formed on the second metal layer 210a. The photoresist film may be formed by a spin coating process. The photoresist film may be patterned by a photolithography process including an exposing process and a developing process to form a photoresist pattern 210b on the second metal layer 210a.

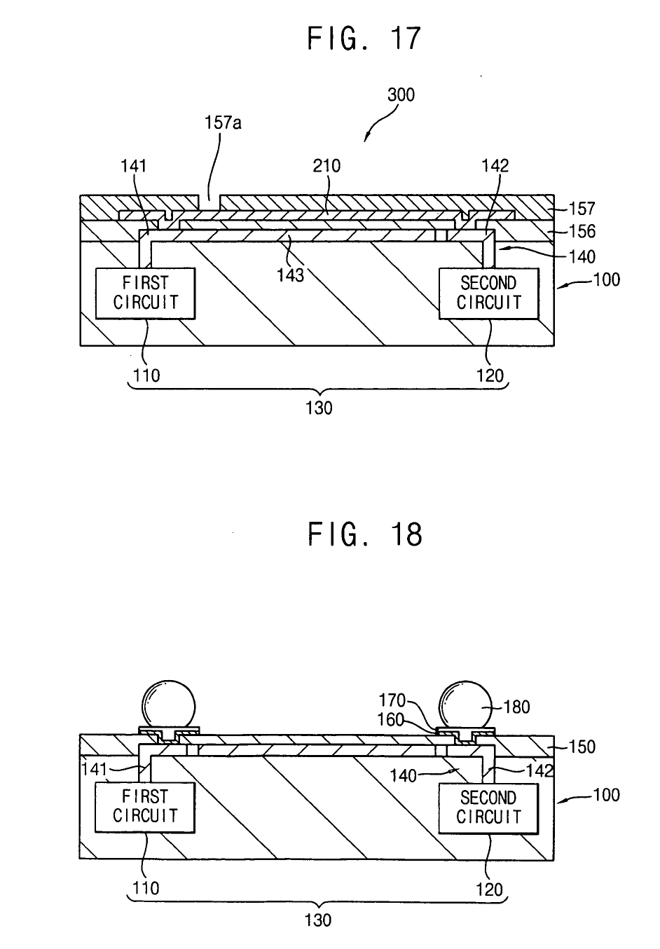

FIG. 17 is a diagram illustrating a second conductive pattern formed by patterning the second metal layer in FIG. 16. Referring to FIG. 17, after forming the photoresist pattern 210b, the second metal layer 210a may be etched using the photoresist pattern 210b as an etching mask to form a second conductive member 210 on the first passivation layer 156. In example embodiments, the first conductive unit 141 may be electrically coupled to the second conductive unit 142 through the second conductive member 210.

After forming the second conductive member 210 on the passivation layer 156, a second passivation layer 157 may be formed on the first passivation layer 156. After the second passivation layer 157 is formed on the first passivation layer 156, a photoresist film (not shown) may be formed on an upper face of the second passivation layer 157. The photoresist film may be formed by a spin coating process. The photoresist film may be patterned by a photolithography process to form an aperture 157a, which partially exposes the second conductive member 210 through the second passivation layer 157.

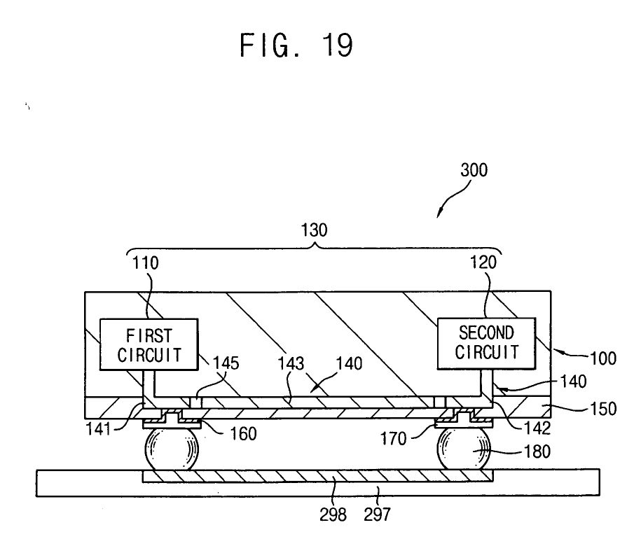

FIG. 18 is a diagram illustrating a semiconductor chip in accordance with example embodiments. Referring to FIG. 18, a conductive pad 160 and a conductive bump 170 may be sequentially formed on an upper face of the semiconductor chip including the passivation layer 150 having the first aperture 152 and the second aperture 154. A solder ball 180 may be attached to the conductive bump 170.

FIG. 19 is a diagram illustrating a semiconductor chip in FIG. 18 mounted to the substrate. Referring to FIG. 19, a second conductive member 298 may be formed on a substrate 297. The solder ball 180 attached to the conductive bump 170 of the semiconductor chip 100 may be mounted to the second conductive member 298 of the substrate 297 in a flip chip manner.

According to example embodiments, a first conductive member for connecting the first and second circuits of the semiconductor chip may be disconnected using the cut-out portion, for example, a fuse and/or a switching element. The first circuit may be electrically connected to the second circuit through the second conductive member, having improved electrical characteristics, to reduce noise caused by a deterioration of the driving signal.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of example embodiments. Accordingly, all such modifications are intended to be included within the scope of the claims. In the claims, means-plus-function clauses are intended to cover the structures described herein as performing the recited function and not only structural equivalents but also equivalent structures. Therefore, it is to be understood that the foregoing is illustrative of example embodiments and is not to be construed as limited to the specific embodiments disclosed and that modifications to the disclosed embodiments, as well as other embodiments, are intended to be included within the scope of the appended claims. Example embodiments are defined by the following claims, with equivalents of the claims to be included therein.

What is claimed is:

1. A semiconductor device, comprising:
a semiconductor chip including a first circuit, a second circuit spaced apart from the first circuit and a first conductive member selectively electrically connecting the first circuit and the second circuit; and
a second conductive member electrically coupled between the first and second circuits.

2. The device of claim 1, wherein the first conductive member includes a cut-out portion for dividing the first conductive member into a first sub-conductive member electrically connected to the first circuit and a second sub-conductive member electrically connected to the second circuit.

3. The device of claim 2, wherein the cut-out portion includes a fuse inserted between the first sub-conductive member and the second sub-conductive member.

4. The device of claim 2, wherein the cut-out portion includes a switching element inserted between the first sub-conductive member and the second sub-conductive member.

5. The device of claim 2, further comprising:
a lead frame on which the semiconductor chip having the first and second sub-conductive members are mounted;
conductive wires for connecting the first sub-conductive member and the lead frame and the second sub-conductive member and the lead frame; and
a substrate electrically connected to the lead frame and having the second conductive member.

6. The device of claim 2, wherein a first conductive ball is mounted on the first sub-conductive member and a second conductive ball is mounted on the second sub-conductive member.

7. The device of claim 1, wherein the second conductive member has a width wider that that of the first conductive member.

8. The device of claim 1, wherein the second conductive member has a greater electrical resistance than that of the first conductive member.

9. The device of claim 1, wherein the second conductive member has a thickness greater than that of the first conductive member.

10. The device of claim 1, wherein the semiconductor chip further comprises:
at least one passivation layer for covering the first conductive member.

11. The device of claim 10, wherein the second conductive member is placed on the at least one passivation layer.

12. The device of claim 10, wherein the at least one passivation layer exposes the first sub-conductive member through a first aperture and the second sub-conductive member through a second aperture.

13. The device of claim 12, wherein a first conductive pad is electrically connected to the first portion of the first sub-conductive member and a second conductive pad is electrically connected to the second portion of the first sub-conductive member.

14. The device of claim 13, wherein a first conductive bump is electrically connected to the first conductive pad and a second conductive bump is electrically connected to the second conductive pad.

15. The device of claim 1, further comprising:
a substrate including the second conductive member.

16. The device of claim 15, wherein the substrate comprises:
a first conductive wire for electrically connecting the second conductive member and the first sub-conductive member; and
a second conductive wire for electrically connecting the second conductive member and the second sub-conductive member.

17. The device of claim 16, wherein the substrate includes a printed circuit board.

18. The device of claim 16, further comprising:
a mold member encapsulates the semiconductor chip, the first conductive wire and the second conductive wire on the substrate.

19. The device of claim 15, further comprising:
an adhesive member for adhering the substrate to a lower face of the semiconductor chip.

20. A method of manufacturing a semiconductor device, comprising:
forming a semiconductor chip including a circuit unit having a first circuit and a second circuit spaced apart from each other on a substrate;
forming a first conductive member for electrically connecting the first and second circuits; and
forming a second conductive member electrically coupled between the first and second circuits.

21. The method of claim 20, further comprising:
forming a cut-out portion for electrically disconnecting the first and second circuits;
applying a test signal to the first circuit and the second circuit through the first conductive member to test the first and second circuits;
selectively removing the cut-out portion in accordance with test results to divide the first conductive member into a first sub-conductive member and a second sub-conductive member; and
electrically connecting the first sub-conductive member to the second sub-conductive member using the second conductive member.

22. The method of claim 21, after testing the first and second circuits, further comprising:
forming a passivation layer having a first aperture that exposes a first portion of the first sub-conductive member and a second aperture that exposes a second portion of the second sub-conductive member.

23. The method of claim 21, wherein electrically connecting the first sub-conductive member to the second sub-conductive member using the second conductive member comprises:
forming the second conductive member on a substrate;
electrically connecting the first sub-conductive member to the second conductive member using a first conductor; and
electrically connecting the second sub-conductive member to the second conductive member using a second conductor.

24. The method of claim 20, wherein the first and second conductive members include a conductive wire.

25. The method of claim 21, further comprising:
forming a first conductive pad on the first sub-conductive member; and
forming a second conductive pad on the second sub-conductive member.

26. The method of claim 25, after forming the first and second conductive pads, further comprising:
forming a first conductive bump on the first conductive pad; and
forming a second conductive bump on the second conductive pad.

27. The method of claim 21, wherein electrically connecting the first sub-conductive member to the second sub-conductive member using the second conductive member comprises:
forming a passivation layer having a first aperture and a second aperture that partially expose the first and second sub-conductive members, respectively;
forming a conductive layer on the passivation layer; and
patterning the conductive layer to form the second conductive member electrically connected to the first and second sub-conductive members that are exposed through the first and second apertures.

28. The method of claim 21, wherein electrically connecting the first sub-conductive member to the second sub-conductive member using the second conductive member comprises:
forming a passivation layer having first and second apertures that partially expose the first and second sub-conductive members, respectively;
forming conductive balls on the exposed first and second sub-conductive members, respectively; and
electrically connecting the conductive balls to the second conductive member formed on a substrate.
